(19) United States
(12) Patent Application Publication
(10) Pub. No.: US 2011/0187264 A1
(43) Pub. Date: Aug. 4, 2011

(54) LIGHT EMITTING DEVICE

(75) Inventors: Hideki YASUDA, Kanagawa-ken (JP); Masayuki NAYA, Kanagawa-ken (JP)

(73) Assignee: FUJIFILM CORPORATION, Tokyo (JP)

(21) Appl. No.: 12/700,167

(22) Filed: Feb. 4, 2010

(30) Foreign Application Priority Data
Jan. 29, 2010 (JP) 019047/2010

(51) Int. Cl. H01L 51/52

(52) U.S. Cl. 313/504; 977/939

(57) ABSTRACT

An organic electroluminescence device having two electrodes and a plurality of organic layers between the two electrodes, in which the organic layers include a light emitting layer that emits light when an electric field is applied between the two electrodes. The device further includes, inside or on the organic layer side of at least either one of the electrodes, a metal structure that generates a surface or local plasmon by light emitted from the light emitting layer, and the metal structure is embedded in a conductive layer and at least a portion of the metal structure is located adjacent to the light emitting layer.

### TECHNICAL FIELD

The present invention generally relates to a light emitting device (electroluminescence device) that emits light when an electric field is applied and more particularly to an organic electroluminescence device with improved light emitting efficiency.

### BACKGROUND ART

Recently, organic EL has been drawing attention for use in illumination, display light sources, and the like. Light emitting materials used for organic EL, however, have a problem of low durability, which makes the organic EL difficult to be put into practical use.

It is known that organic materials inherently remain in exited state for a long time, whereby the chemical bonding of the materials is broken and the light emission performance is degraded with time. This low durability is a big challenge in employing an organic substance to a light emitting device.

Typically, organic EL devices have a structure in which an electrode layer and a plurality of organic layers are laminated on a substrate and light emitted from a light emitting layer is outputted through a transparent electrode. In this structure, the light incident on each interface between the layers on the light output side at an angle greater than the critical angle is totally reflected back and contained inside of the device, thereby unable to extract the light to the outside. Consequently, it is difficult to efficiently extract the emitted light, and it is said that the light extraction efficiency is about 20% for a transparent electrode having a refractive index of ITO or the like which is being used commonly as a material of transparent electrode.

Patent Document 1 proposes a technique for improving the light extraction efficiency of an organic EL device by disposing a scattering layer which includes metal fine particles inside of the device and scattering the emitted light.

In the mean time, Non-patent Document 1 describes that the exciton lifetime of a dye placed adjacent to a metal fine particle is reduced and the durability is improved. In relation to this, Non-patent Document 2 proposes a method for enhancing emission of an organic light emitting device by disposing an island shaped metal near a light emitting layer. This emission enhancement is due to the fact that the dipole radiation from the light emitting device induces a surface plasmon (local plasmon) on the metal surface and energy is absorbed which is then reradiated as a new emission. That is, a new emission transition induced by the plasmon is added to the original emission process of the light emitting device, whereby advantageous effects of reducing the upper level lifetime (radiactive lifetime) may be obtained. In this way, it is expected that the utilization of plasmon resonance may provide advantageous effects of improving the durability of the light emitting device through radiactive lifetime reduction, as well as improving the light emission efficiency.

### PRIOR ART DOCUMENTS

### Patent Documents

[Patent Document 1] Japanese Unexamined Patent Publication No. 2007-165284.

### Non-Patent Documents

[Non-patent Document 1] J. R. Lakowicz et al., “Radiative decay engineering. 2. Effects of Silver Island Films on Fluorescence Intensity, Lifetimes, and Resonance Energy Transfer”, Analytical Biochemistry, Vol. 301, Issue 2, pp. 261-277, 2002.
[Non-patent Document 2] W. Li et al., “Emissive Efficiency Enhancement of Alg₃ and Prospects for Plasmon-enhanced Organic Electroluminescence”, Proc. of SPIE, vol. 7032, pp. 703224-1-703224-7, 2008.

### DISCLOSURE OF THE INVENTION

### Problems to be Solved by the Invention

But, in Non-patent Document 2, the emission enhancement due to the plasmon enhancement effect is confirmed only for photoexited light emitting devices (photoluminescence devices (PL devices)), and no report of successful example is found for field exited EL devices.

The present invention has been developed in view of the circumstances described above, and it is an object of the present invention to provide an organic EL device having an improved durability by reducing the exciton lifetime.

### Means for Solving the Problems

An organic electroluminescence device of the present invention is a device, including two electrodes and a plurality of organic layers between the two electrodes, the organic layers including a light emitting layer that emits light when an electric field is applied between the two electrodes, wherein:

the device further includes, inside or on the organic layer side of at least either one of the electrodes, a metal structure that generates a surface or local plasmon by light emitted from the light emitting layer; and

the metal structure is embedded in a conductive layer and at least a portion of the metal structure is located adjacent to the light emitting layer.

The term “at least a portion of the metal structure is located adjacent to the light emitting layer” as used herein refers to that at least a portion of the metal structure is disposed at a distance from the light emitting layer close enough to cause plasmon resonance effects to occur by a surface or local plasmon. Preferably, the shortest distance between the portion of the metal structure and light emitting layer is not greater than 30 nm in order to cause plasmon resonance effects to occur.

When the metal structure is provided inside of either one of the electrodes, the conductive layer described above is the either one of the electrodes itself. When the metal structure is provided on the organic layer side of the either one of the electrodes, the conductive layer is a conductive organic layer, such as a hole injection layer, an electron injection layer, a hole transport layer, an electron transport layer, or the like.

As for the material of the metal structure, any material may be used as long as it is capable of generating a plasmon resonance by the light emitted from the light emitting layer, and a metal, such as Ag (silver), Au (gold), Pt (platinum), Cu (copper), Al (aluminum), or the like, or an alloy that includes one of these metals as the major component is preferably used. The term “major component” as used herein refers to a component with a content of 80% by mass or more.

The either one of the electrodes may be an anode or a cathode. Further, the either one of the electrodes may be formed of a metal or a transparent conductive material. Examples of transparent conductive materials include ITO (indium titanium oxide), ZnO (zinc oxide), and the like.

When the either one of the electrodes is formed of a metal, it may be a semi-transmissive metal electrode formed of Ag, Mg, or an alloy that includes one of these metals as the major component, or it may be an opaque metal electrode formed of Al, Mg, Ag, Cu, Ca, or an alloy that includes one of these metals as the major component.

Further, the either one of the electrodes may be formed of a conductive material which is less likely to generate a surface plasmon by the light emitted from the light emitting layer than a metal of the metal structure. The metal structure may be a metal film having an uneven pattern with a period smaller than a wavelength of the light emitted from the light emitting layer or a solid metal film.

As for the metal film having an uneven pattern, any nanostructure film formed of a metal mesh, metal nanoparticles, metal nanorods, or the like may be used, and a metal fine particle film formed of a multitude of metal fine particles (metal nanoparticles) with a particle diameter of 10 to 500 nm is particularly preferable. The disposition of the metal fine particles may be at random or periodic. The term “particle size” as used herein refers to a maximum length of a metal fine particle. For example, if the metal fine particle has a spherical shape, the particle size refers to the diameter, and if the metal fine particle has a rod shape, the particle size refers to the long diameter.

It is preferable that the metal structure accounts for not less than 5% of the area of the either one of the electrodes. The term “the metal structure accounts for not less than 5% of the area of the either one of the electrodes” as used herein refers to that, when the metal structure is projected onto the electrode surface, the projected image of the metal structure accounts for not less than 5% of the area of the electrode surface.

Preferably, in the organic electroluminescence device of the present invention, the either one of the electrodes is formed on a substrate.

### Advantageous Effect of the Invention

The organic electroluminescence device of the present invention includes, inside or on the organic layer side of at least either one of the electrodes, a metal structure that generates a plasmon resonance by the light emitted from the light emitting layer and at least a portion of the metal structure is located adjacent to the light emitting layer. This may provide both the emission enhancement and exciton lifetime reduction by the emission transition caused by the plasmon. By reducing the time of excition state having a high reactivity with an environmental substance, the durability of the device may be improved.

Further, the organic electroluminescence device of the present invention has a structure in which a metal structure is provided inside or on the organic layer side of either one of the electrodes. This may simplify the manufacturing process in comparison with a structure in which a metal structure is provided inside of a plurality of organic layers located away from the electrode.

### BRIEF DESCRIPTION OF THE DRAWINGS

FIG. 1 is a cross-sectional view of an organic EL device according to a first embodiment of the present invention, schematically illustrating the layer structure thereof.

FIG. 2 is a drawing for explaining the ratio of the metal structure to the electrode area.

FIG. 3 is a cross-sectional view of an organic EL device according to a second embodiment of the present invention, schematically illustrating the layer structure thereof.

FIG. 4 is a cross-sectional view of an organic EL device according to a third embodiment of the present invention, schematically illustrating the layer structure thereof.

FIG. 5 is a cross-sectional view of an organic EL device of Comparative Example 2, schematically illustrating the layer structure thereof.

### BEST MODE FOR CARRYING OUT THE INVENTION

Hereinafter, electroluminescence devices (EL devices) according to embodiments of the present invention will be described with reference the accompanying drawings. In the drawings, each component is not drawn to scale in order to facilitate visual recognition.

### First Embodiment

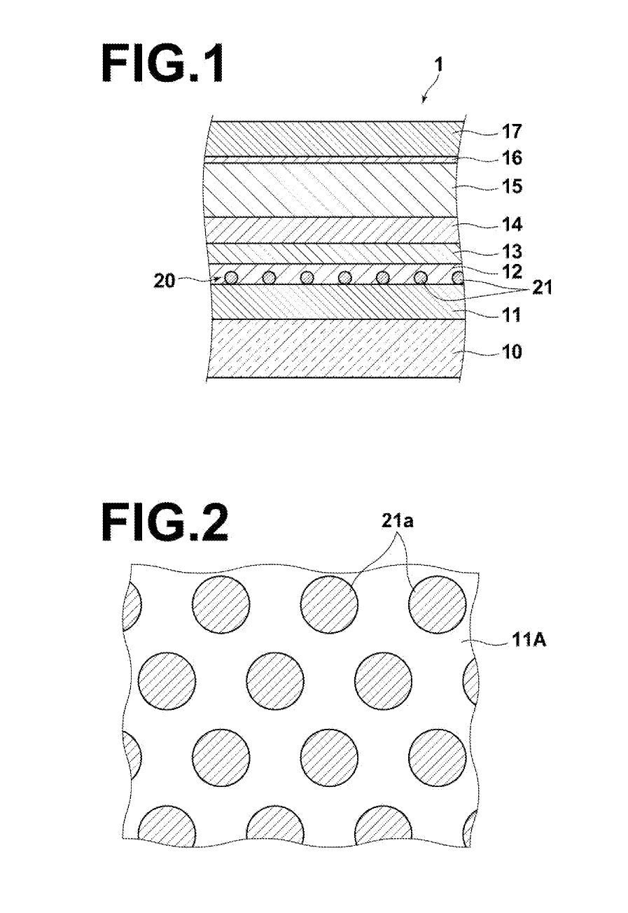

FIG. 1 is a cross-sectional view of organic EL device 1 according to a first embodiment of the present invention, schematically illustrating the structure thereof.

Organic EL device 1 of the present embodiment includes transparent substrate 10, formed of a glass or the like, on which anode 11 having an optical transparency, hole injection layer 12, hole transport layer 13, light emitting layer 14, electron transport layer 15, electron injection layer 16, and cathode 17 are laminated in this order. Device 1 further includes a metal structure 20 formed of metal fine particles 21 that generate plasmon resonance by the light emitted from light emitting layer 14. Metal fine particles 21 are formed so as to contact the surface of anode 11 and hole injection layer 12 formed of a conductive organic substance is filled between metal fine particles 21.

Organic EL device 1 is structured such that the light emitted from light emitting layer 14 when an electric field is applied between electrodes 11 and 17 exits from the side of anode 11.

Note that FIG. 1 is a schematic view of organic EL device 1 and metal fine particles are depicted such that they are completely embedded in hole injection layer 12 and the upper surface of the hole injection layer 12 is flat. But, in an actual device produced by a manufacturing method to be described later, hole injection layer 12 is formed along the surfaces of particles 21. Consequently, the upper surface (lamination plane) of the hole injection layer is waved along particles 21, the upper surface of each layer further laminated thereon is also waved accordingly. As the layer thickness from the particles increases, the degree of waviness of the lamination plane is moderated.

Light emitting layer 14 is a light emitting area that emits light through the recombination of electrons and holes injected from anode 11 and cathode 17. There is not any specific restriction on the material of light emitting layer 14 as long as it is applicable to the light emitting layer of an organic EL device and a material may be selected according to a desired emission wavelength.

Anode 11 may be a transparent electrode formed of a transparent conductive material such as ITO or ZnO. Alternatively, it may be a semi-transmissive metal electrode formed of Ag, Mg or an alloy that includes one of these metals as the major component. In the case of a metal electrode, the optical transparency is provided by thinly forming the electrode.

In the present embodiment, metal structure 20, which is a metal fine particle film having a multitude of metal fine particles 21 formed therein, is one form of a film having an uneven structure smaller than a wavelength of the light emitted from light emitting layer 14. Metal fine particles 21 may be disposed periodically or at random.

As for the material of metal structure 20 (metal fine particle 21), any material capable of generating a surface or local plasmon resonance by light emitted from light emitting layer 14 may be used, and Au, Ag, Pt, Cu, Al, or an alloy having one of them as the major component may preferably be used.

Preferably, metal fine particle 21 has a diameter of 10 to 500 nm. A particle diameter smaller than 10 nm results in that the plasmon resonance wavelength falls in the ultraviolet region and a particle diameter greater than 500 nm results in that the plasmon resonance wavelength falls in the infrared region, so that the plasmon resonance effect becomes small.

Further, metal structure 20 is disposed at a distance from light emitting layer 14 close enough to cause plasmon resonance effects to occur by a surface or local plasmon and at least a part of the structure is located adjacent to light emitting layer 14. A too long distance from light emitting layer 14 results in a plasmon resonance with emitted light becomes difficult to occur, so that the emission enhancement effect can not be obtained. Thus, it is preferable that at least a part of metal structure 20 is placed at a distance of not greater than 30 nm from light emitting layer 14. The distance between metal structure 20 and light emitting layer 14 as used herein refers to a distance closest between each portion thereof (shortest distance).

On the other hand, if metal structure 20 is in contact with light emitting layer 14 or in proximity to light emitting layer 14 at a distance “d” less than 5 nm, charge migration occurs directly from light emitting layer 14 and emission decay is highly likely to occur. Thus, it is preferable that metal structure 20 is placed away from light emitting layer 14 at a distance greater than 5 nm.

When metal structure 20 is projected onto the surface of electrode 11, it is preferable that the projected image of the metal structure accounts for 5% or more of the area of the electrode surface. FIG. 2 illustrates projected images 21a of the particles constituting metal structure 20 projected on surface 11A of electrode 11. As shown in FIG. 2, it is preferable that the projected images 21a account for 5% or more of the area of electrode surface 11A. A smaller ratio of the projected image of metal structure to the area of the electrode surface results in a plasmon resonance between the fine particles and light emitted from light emitting layer 14 becomes difficult to occur, so that the emission enhancement effect and durability improvement effect through radiactive lifetime reduction can not be obtained. Thus, it is preferable that the ratio is not smaller than 5%. If the metal structure is provided on the electrode on the light output side, it is necessary to provide a gap between the particles so that a transmittance of about 40% is ensured for the light emitted from light emitting layer 14 in order to output the emitted light. If the metal structure is provided on the electrode not on the light output side, on the other hand, the ratio of projected image of the metal structure to the electrode surface may be 100%.

Organic EL device 1 of the present invention includes metal structure 20 constituted by the metal fine particle film described above and placed such that a portion thereof is located adjacent to light emitting layer 14 (at a distance not greater than 30 nm), whereby emission enhancement effect and upper level lifetime (radiactive lifetime) reduction effect may be obtained by a plasmon resonance between the emitted light and metal fine particles. This may improve the light emission efficiency and durability through the radiactive lifetime reduction.

Metal structure 20 constituted by metal fine particles 21 may be formed, after forming anode 11 formed of a transparent material, such as ITO or the like, on substrate 10, by depositing a metal layer on anode 11 with a thickness of about 10 nm and annealing the metal layer at a predetermined temperature.

The organic EL device of the present embodiment may be manufactured, after forming anode 11 on substrate 10 and metal structure 10 in the manner as described above, by serially laminating, through deposition, hole injection layer 12, hole transport layer 13, light emitting layer 14, electron transport layer 15, electron injection layer 16, and cathode 17 on anode 11 having metal structure 20.

As described above, the organic EL device of the present embodiment includes a metal structure adjacent to anode 11 on substrate 10 and organic layers 12 to 16 are formed to embed the metal structure, so that the organic EL device may be manufactured by a simple manufacturing process.

In the embodiment described above, each organic layer, such as hole injection layer 12, hole transport layer 13, light emitting layer 14, electron transport layer 15, or electron injection layer 16, may be formed of a material selected from those which are known to have the respective functions. Further, the organic EL device may further include a hole blocking layer, an electron blocking layer, a protection layer, and the like.

The organic EL device according to the first embodiment described above has a lamination structure in which the anode electrode is formed first on glass substrate 10, but identical effects may be obtained when the device is configured to have a lamination structure in which the cathode electrode is formed first on substrate 10 and metal structure 20 is formed on the cathode electrode if metal structure 20 is formed such that at least a portion thereof is placed adjacent to the light emitting layer.

The organic EL device according to the first embodiment described above includes a transparent electrode on substrate 10 and is configured to output emitted light from the substrate side. Alternatively, the device may include an opaque metal electrode of Al, Mg, Ag, Cu, Ca, or the like on substrate 10 and an electrode that transmits the emitted light on the organic layers, and is configured to output the emitted light from a face opposite to the substrate.

In this case, the metal structure may be provided on the metal electrode. The metal electrode is formed first (first layer) on the substrate and then the metal film (second layer) is formed. The second layer metal may be of a type that is same or different from the constituent material of the metal electrode. Then, the metal structure may be formed on the metal electrode by selectively etching a portion of the second layer metal. Here, the solid film of the first layer portion is used as the metal electrode and the second layer structure is used as the metal structure.

Further, in the organic EL device according to the first embodiment, metal structure 20 is provided on anode 11 on the organic layer side and embedded in hole injection layer 21, which is a conductive organic layer. But, metal structure 20 may be provided inside of anode 11.

### Second Embodiment

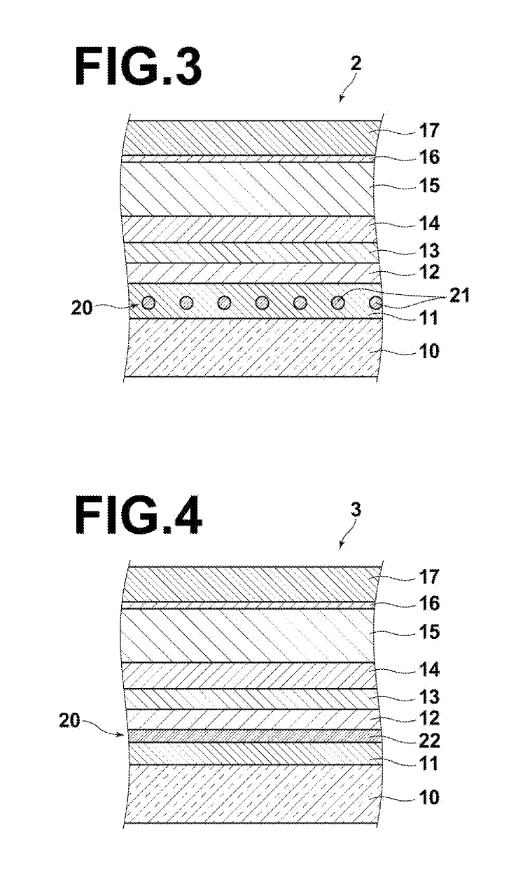

FIG. 3 is a cross-sectional view of organic EL device 2 according to a second embodiment of the present invention, schematically illustrating the structure thereof. Components identical to those of the organic EL device 1 in Figures that will be described hereinafter are given the same reference numerals.

Organic EL device 2 differs from organic EL device 1 according to the first embodiment in that metal structure 20 is disposed inside of anode 11 instead of on anode 11. In organic EL device 2, metal structure 20 inside of anode 11 is disposed at a distance from light emitting layer 14 close enough to cause a plasmon resonance to occur by the light emitted from light emitting layer 14.

In the present embodiment, anode 11 is formed of a transparent conductive material that does not generate a surface or local plasmon by the light emitted from light emitting layer 14 or a metal which is more unlikely to generate a surface or local plasmon by the emitted light than the metal of metal structure 20. In doing so, metal structure 20 and anode 11 become clearly distinguishable from each other because of the material difference and the advantageous effect of metal structure 20 appears more significantly.

Organic EL device 2 of the present embodiment includes metal structure 20 constituted by the metal fine particle film and placed such that a portion thereof is located adjacent to light emitting layer 14 as in the first embodiment, so that emission enhancement effect and upper level lifetime (radiactive lifetime) reduction effect, which improves the durability of the device, may be obtained by a plasmon resonance between the light emitted from light emitting layer 14 and metal fine particles.

One of specific methods for forming metal structure 20 inside of a transparent conductive material may be a method in which a transparent electrode is formed on a substrate, then a metal layer is formed thereon and annealed at a predetermined temperature, and a metal layer is further formed.

As described above, in the organic EL device of the present embodiment, a metal structure is provided inside of anode 11 on substrate 10, so that the organic EL device may be manufactured by a simple manufacturing process.

In each aforementioned embodiment, the description has been made of a case in which metal structure 20 is a metal fine particle film. But, metal structure 20 may be formed of not only the film of metal fine particle but also of a metal mesh or a metal nanostructure of metal nanorods. The mesh or rods may be disposed periodically or at random. Further, metal structure may be a smooth solid film other than the metal nanostructure.

### Third Embodiment

FIG. 4 is a cross-sectional view of organic EL device 3 according to a third embodiment of the present invention, schematically illustrating the structure thereof.

Organic EL device 3 differs from organic EL device 1 according to the first embodiment in that metal structure 20 is formed of solid metal film 22 uniformly provided on the surface of anode 11 on the organic layer side.

After forming anode 11 on glass substrate 10, metal film 22 may be formed, through deposition, on anode 11. In organic EL device 3 configured to output the emitted light from the side of anode 11, metal film 22 needs to be transparent to the emitted light. Therefore, metal film 22 is formed sufficiently thin to ensure a sufficient optical transparency (transmittance of about 40% or more).

Organic EL device 3 of the present embodiment includes metal structure 20 constituted by metal film 22 and placed such that a portion thereof is located adjacent to light emitting layer 14 as in the first embodiment, so that emission enhancement effect and upper level lifetime (radiactive lifetime) reduction effect, which improves the durability of the device, may be obtained by a plasmon resonance between the emitted light and metal fine particles.

Where the metal structure is a solid metal film as in the present embodiment, although a surface plasmon is induced by the light emitted from light emitting layer 14, re-coupling to radiation mode is hardly likely to occur and mostly lost as heat in non-radiation process in the end. On the other hand, if the metal structure is a nanostructure film, the surface plasmon caused on the film surface by the light emitted from light emitting layer 14 is re-coupled to the radiation mode and highly efficiently radiates light. Preferably, therefore, the metal structure is a nanostructure having an uneven structure smaller than the wavelength of the light emitted from light emitting layer.

In each of aforementioned embodiments, the description has been made of a case in which the device has metal structure 20 formed on or inside of only one of electrodes 11 and 17 but metal structure 20 may be formed on or inside of each of electrodes 11 and 17.

### Example 1

Example 1 and Comparative Examples 1 and 2 having a structure of EL device 1 of the first embodiment were produced to perform the following experiments.

### Example 1

A glass substrate was used as transparent substrate 10 and an organic EL device of Example 1 was produced by depositing the following in the order described below.

First, an ITO film was formed on glass substrate 10 as anode 11 with a thickness of 100 nm. Then, an Ag film was formed on the ITO film and the Ag film was heated (annealed) at 300° C. for 60 minutes under N₂ environment to obtain fine particle film (metal structure) 20 constituted by Ag fine particles with a particle diameter of 50 to 100 nm. Thereafter, as hole injection layer 12, 2-TNATA (4,4,4-Tris(2-naphthylphenylamino)triphenylamine) and F4-TCNQ were deposited with a thickness of 10 nm such that F4-TCNQ becomes 0.3%. Then, as hole transport layer 13, NPD (N,N′-dinaphthyl-N,N′-diphenyl [1,1′-biphenyl]) was deposited with a thickness of 10 nm and further, as light emitting layer 14, CBP-10% Ir(ppy)₃ was formed with a thickness of 30 nm. Then, as electron transport layer 15, BAIq was formed with a thickness of 150 nm, as electron injection layer 16, LiF was formed with a thickness of 1 nm, and as cathode 17, Al was formed with a thickness of 100 nm. Finally, the lamination was sealed with an UV adhesive and the organic EL device of Example 1 was completed.

### Comparative Example 1

An organic EL device having a structure similar to that of Example 1 but without having the Ag particle film (metal structure) 20 was manufactured as Comparative Example 1 by the manufacturing process similar to that of Example 1 but without having the Ag deposition and annealing at 300° C.

### Comparative Example 2

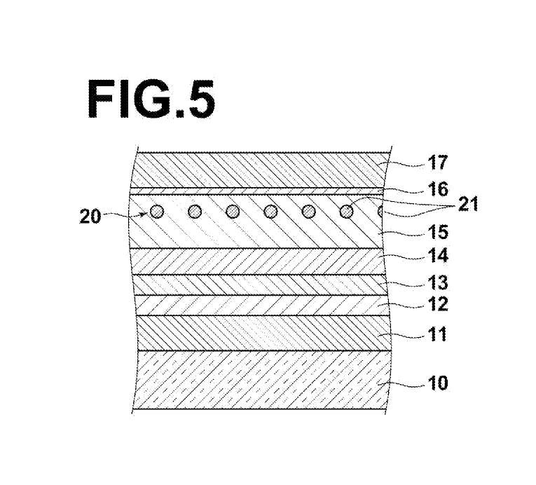

Comparative Example 2 was produced by a manufacturing process similar to that of Example 1 except that the Ag deposition and annealing at 300° C. were omitted and, in the process of depositing BAIq with a thickness of 150 nm, as electron transport layer 15, BAIq was deposited with a thickness of 50 nm, then Ag was deposited on the BAIq layer with a thickness of 10 nm, and BAIq was further deposited with a thickness of 100 nm. FIG. 5 is a cross-sectional view of the organic EL device of Comparative Example 2, schematically illustrating the layer structure thereof.

Observation of a cross-section of the device with SEM (scanning electron microscope) showed that the Ag layer was turned into a fine particle film constituted by Ag fine particles of 40 to 50 nm.

### <Emission Lifetime Measurements>

Each organic EL device of Example 1 and Comparative Examples 1 and 2 is irradiated with nitrogen laser light (wavelength 337 nm, pulse with 1 ns), as the excitation light, and the lifetime of emission from each light emitting material was measured with a streak camera (C4334, Hamamatsu Photonics K.K., Japan).

### <EL Operation Half-lifetime Measurements>

A DC current value that causes each organic EL device of Example 1 and Comparative Examples 1 and 2 to provide a luminance of 2000 cd/m² was measured and each device was continuously operated with the current value to measure the time from the start to the time when the luminance is reduced to 1000 cd/m².

The emission lifetime and EL operation half-lifetime of each device are shown in Table 1. It has been confirmed that, in comparison with Comparative Examples 1 and 2, Example 1 has a shorter emission lifetime and a longer EL operation durability, as shown in Table 1.

TABLE 1

| | E/Lifetime(μs) | EL O/Half-lifetime (h) |
|---|---|---|
| Example 1 | 0.57 | 1470 |
| C/Example 1 | 0.96 | 1100 |
| C/Example 2 | 0.92 | 1150 |

### EXPLANATION OF REFERENCE NUMERALS

1, 2, 3 Organic EL Device
10 Transparent Substrate
11 Anode
12 Hole Injection Layer
13 Hole Transport Layer
14 Light Emitting Layer
15 Electron Transport Layer
16 Electron Injection Layer
17 Cathode
20 Metal Structure
21 Metal fine particle
22 Sold Metal Film

1. An organic electroluminescence device, comprising two electrodes and a plurality of organic layers between the two electrodes, the organic layers including a light emitting layer that emits light when an electric field is applied between the two electrodes, wherein:
the device further comprises, inside or on the organic layer side of at least either one of the electrodes, a metal structure that generates a surface or local plasmon by light emitted from the light emitting layer; and
the metal structure is embedded in a conductive layer and at least a portion of the metal structure is located adjacent to the light emitting layer.

2. The organic electroluminescence device of claim 1, wherein the either one of the electrodes is formed of a transparent conductive material.

3. The organic electroluminescence device of claim 1, wherein the either one of the electrodes is formed of a conductive material which is less likely to generate a surface plasmon by the light emitted from the light emitting layer than a metal of the metal structure.

4. The organic electroluminescence device of claim 1, wherein the metal structure is a metal film having an uneven pattern with a period smaller than a wavelength of the light emitted from the light emitting layer.

5. The organic electroluminescence device of claim 4, wherein the metal film is a metal fine particle film formed of a multitude of metal fine particles with a particle diameter of 10 to 500 nm.

6. The organic electroluminescence device of claim 1, wherein the metal structure accounts for not less than 5% of the area of the either one of the electrodes.

7. The organic electroluminescence device of claim 1, wherein the metal structure is a solid metal film formed on the side facing the organic layers of the either one of the electrodes.

8. The organic electroluminescence device of claim 1, wherein the either one of the electrodes is formed on a substrate.
